(19) United States
(12) Patent Application Publication
(10) Pub. No.: US 2026/0123475 A1
(43) Pub. Date: Apr. 30, 2026

(54) Method for Integration of Chiplets and Related Structure

(71) Applicant: Newport Fab, LLC dba Tower Semiconductor Newport Beach, Newport Beach, CA (US)

(72) Inventors: Venkat Dukkipati, San Juan Capistrano, CA (US); David J. Howard, Irvine, CA (US)

(21) Appl. No.: 18/933,056

(22) Filed: Oct. 31, 2024

(51) Int. Cl. H01L 23/498; H01L 21/311; H01L 21/762; H01L 23/48; H01L 23/532; H01L 25/16; H01L 33/30

(52) U.S. Cl. CPC H10W 70/635; H10H 20/824; H10P 50/286; H10P 50/73; H10P 90/1908; H10W 10/061; H10W 10/181; H10W 20/48; H10W 90/00; H10W 20/20

(57) ABSTRACT

In fabricating a semiconductor structure, a substrate is provided. A chiplet is bonded to the substrate. The chiplet includes a bulk layer and an active layer. A hardmask is formed over the chiplet. A photoresist is formed over the hardmask. A photoresist segment is removed to expose a hardmask segment. The exposed hardmask segment is removed to expose the bulk layer without exposing the active layer. The bulk layer is removed. The remainder of the photoresist is removed. A blanket dielectric is formed over the active layer and the hardmask. The blanket dielectric is planarized. A first device is formed from the active layer.

### BACKGROUND

Optoelectronic devices are commonly utilized in data communications. Various applications of optoelectronic devices can utilize an electro-optical effect to affect changes in optical properties (such as phase, amplitude, wavelength, polarization, etc.).

Certain materials, such as group III-V compound semiconductors or Pockels material, have characteristics that make them advantageous for use in optoelectronic devices.

However, operations that are incidental to and supportive of these optoelectronic devices, such as input/output coupling, feedback, and modulation, may be more easily implemented using a different type of material, such as group IV semiconductors, such as silicon.

In one approach, dies of a first material type are heterogeneously integrated on substrates of a second material type. Carrier or bulk layers are used for handling the dies during integration, and then the bulk layers are removed, leaving active layers of the dies, which can be fashioned into optoelectronic devices. However, conventional techniques for removing bulk layers tend to leave residual structures that require complex design considerations. More actions are often needed to completely remove bulk layers, increasing fabrication time and cost. Further, forming optoelectronic devices with predetermined dimensions can require starting with larger dies in order to account for the volumes of bulk layers that will become residual structure, thereby leaving less area for integrating other elements.

Conventional techniques can also fail to properly protect active layers during removal of bulk layers, due to poor encapsulation of the active layers and/or due to the protective layers notwithstanding the harsh additional actions needed to completely remove the bulk layers. Damage to active layers negatively impacts the performance of optoelectronic devices formed therefrom. Moreover, integrated structures can also have significant layer contouring between areas overlying an optoelectronic device and areas overlying adjacent elements. Processing such non-planar topologies can require specialized fabrication technologies, and can make lithography and alignment difficult such that smaller devices are more prone to fabrication errors.

Thus, there is need in the art to more efficiently and effectively integrate heterogenous structures with improved performance and reduced complexity.

### SUMMARY

The present disclosure is directed to methods for integration of chiplets and related structures, substantially as shown in and/or described in connection with at least one of the figures, and as set forth in the claims.

### BRIEF DESCRIPTION OF THE DRAWINGS

FIG. 1A illustrates a portion of a flowchart of an exemplary method for manufacturing a semiconductor structure according to one implementation of the present application.

FIG. 1B illustrates a portion of a flowchart of an exemplary method for manufacturing a semiconductor structure, as a continuation to the flowchart of FIG. 1A, according to one implementation of the present application.

FIG. 2A illustrates a layout of a semiconductor structure processed in accordance with the flowchart of FIG. 1A according to one implementation of the present application.

FIG. 2B illustrates a cross-sectional view of a portion of a semiconductor structure corresponding to FIG. 2A processed in accordance with the flowchart of FIG. 1A according to one implementation of the present application.

FIG. 3 illustrates a cross-sectional view of a portion of a semiconductor structure processed in accordance with the flowchart of FIG. 1A according to one implementation of the present application.

FIG. 4A illustrates a layout of a semiconductor structure processed in accordance with the flowchart of FIG. 1A according to one implementation of the present application.

FIG. 4B illustrates a cross-sectional view of a portion of a semiconductor structure corresponding to FIG. 4A processed in accordance with the flowchart of FIG. 1A according to one implementation of the present application.

FIG. 5 illustrates a cross-sectional view of a portion of a semiconductor structure processed in accordance with the flowchart of FIG. 1A according to one implementation of the present application.

FIG. 6 illustrates a cross-sectional view of a portion of a semiconductor structure processed in accordance with the flowchart of FIG. 1A according to one implementation of the present application.

FIG. 7 illustrates a cross-sectional view of a portion of a semiconductor structure processed in accordance with the flowchart of FIG. 1A according to one implementation of the present application.

FIG. 8 illustrates a cross-sectional view of a portion of a semiconductor structure processed in accordance with the flowchart of FIG. 1A according to one implementation of the present application.

FIG. 9 illustrates a cross-sectional view of a portion of a semiconductor structure processed in accordance with the flowchart of FIG. 1B according to one implementation of the present application.

FIG. 10 illustrates a cross-sectional view of a portion of a semiconductor structure processed in accordance with the flowchart of FIG. 1B according to one implementation of the present application.

FIG. 11 illustrates a cross-sectional view of a portion of a semiconductor structure processed in accordance with the flowchart of FIG. 1B according to one implementation of the present application.

FIG. 12 illustrates a cross-sectional view of a portion of a semiconductor structure processed in accordance with the flowchart of FIG. 1B according to one implementation of the present application.

FIG. 13 illustrates a cross-sectional view of a portion of a semiconductor structure processed in accordance with the flowchart of FIG. 1B according to one implementation of the present application.

FIG. 14 illustrates a cross-sectional view of a portion of a semiconductor structure processed in accordance with the flowchart of FIG. 1B according to one implementation of the present application.

FIG. 15 illustrates a cross-sectional view of a portion of a semiconductor structure processed in accordance with the flowchart of FIG. 1B according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions. As used herein, “over” may refer to directly or indirectly over.

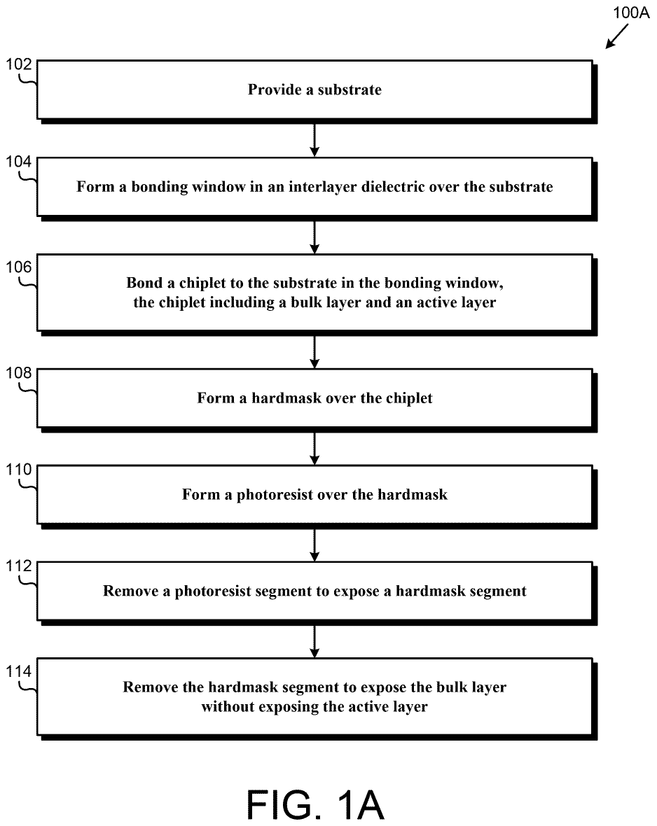

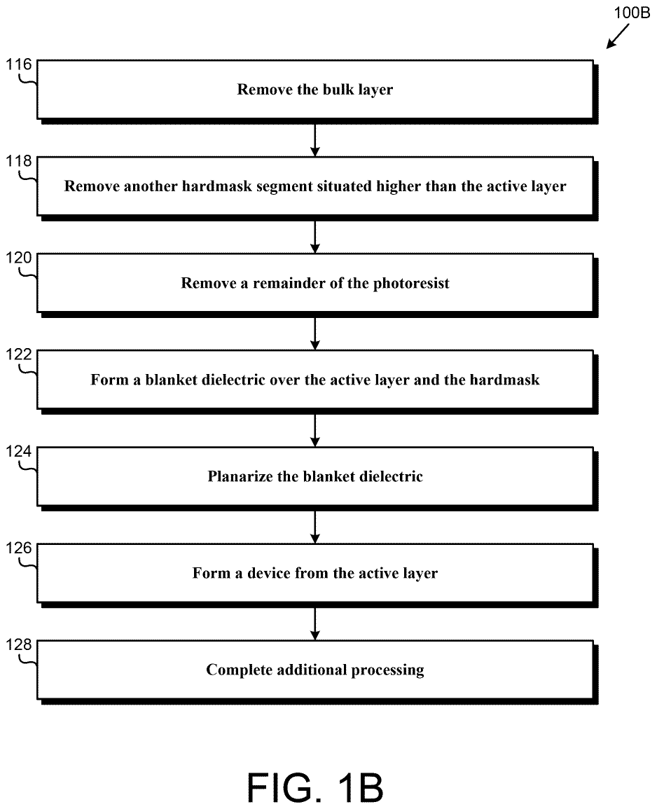

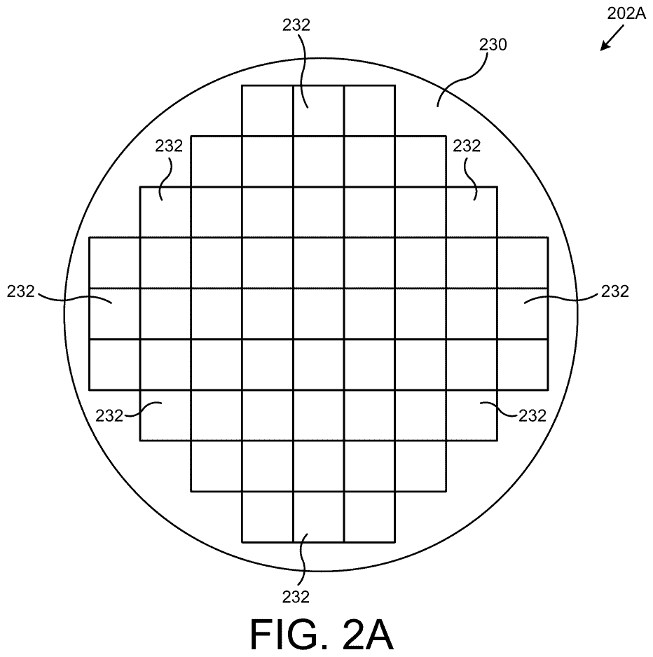

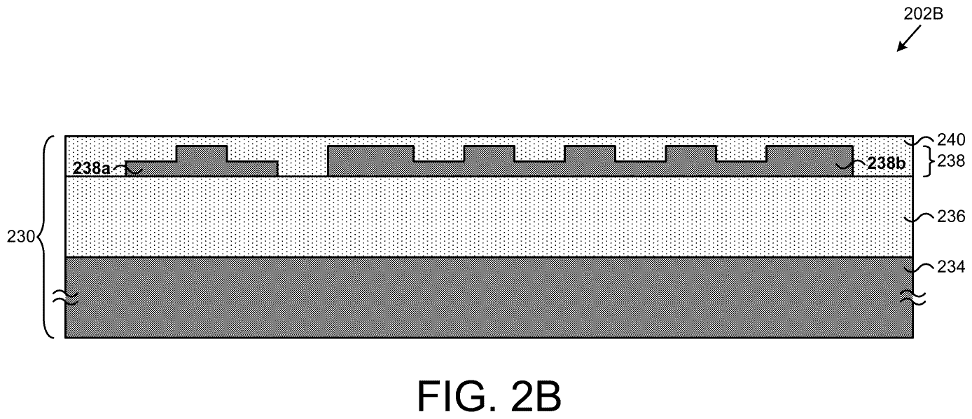

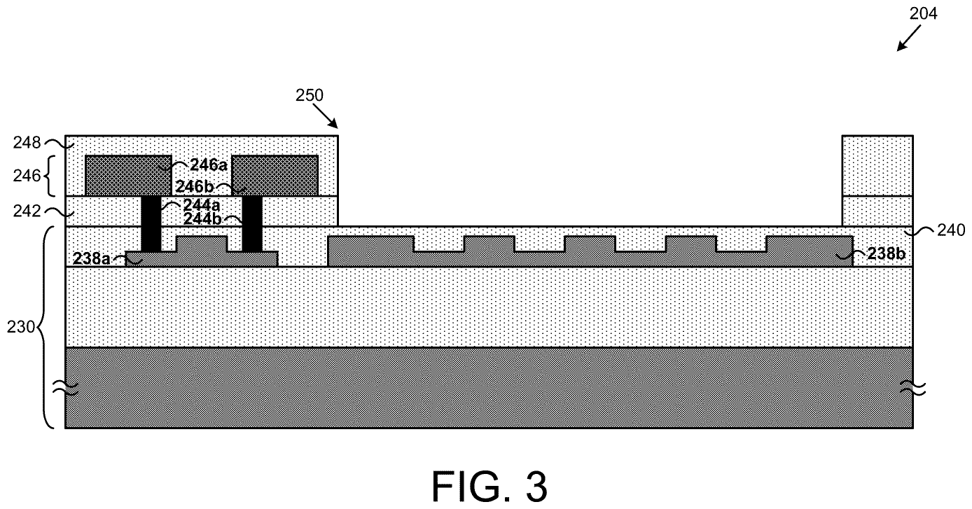

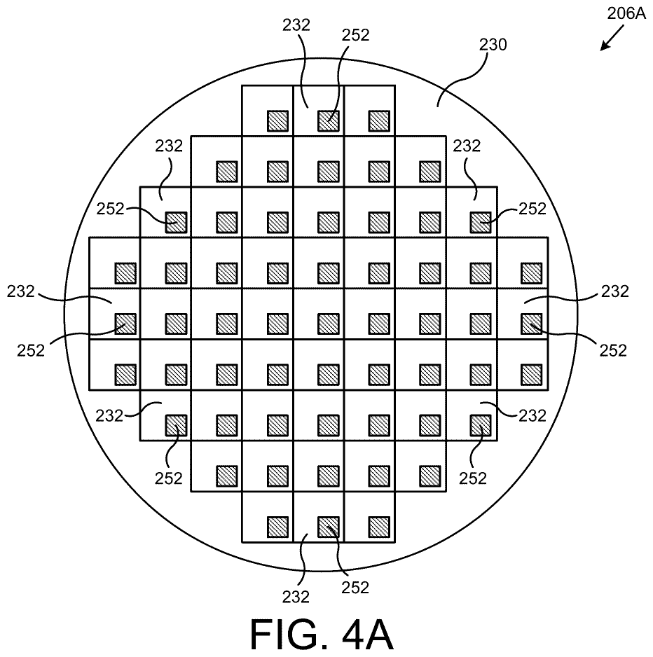

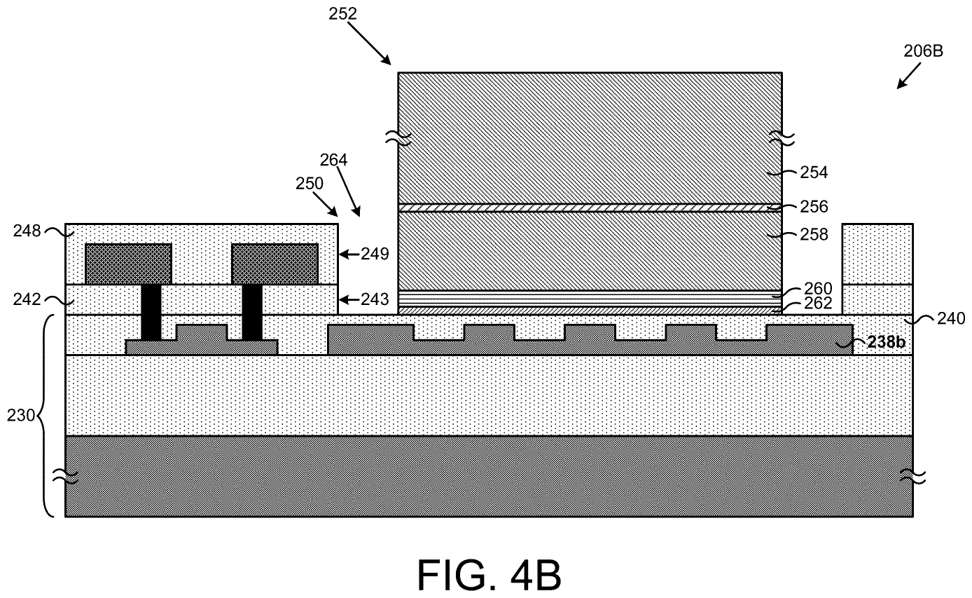

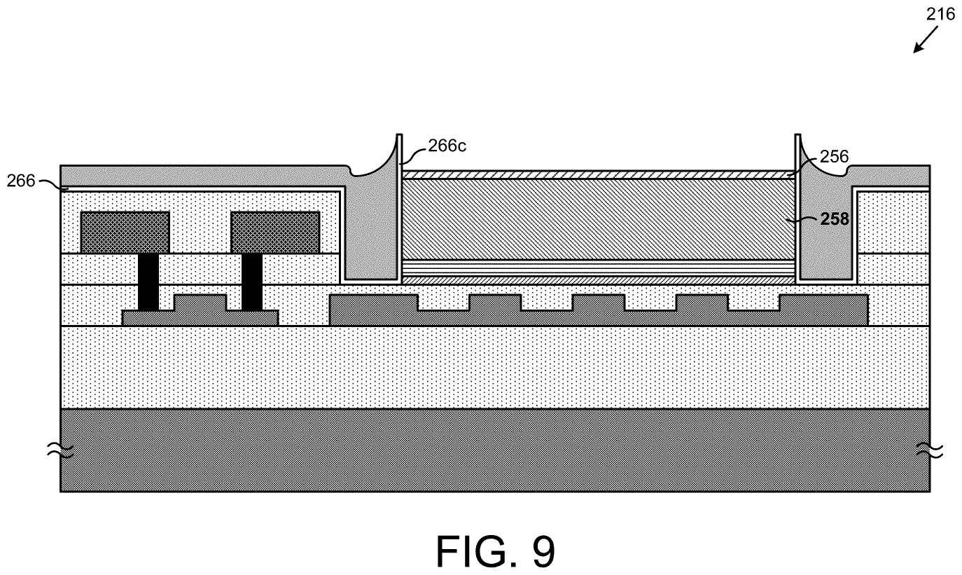

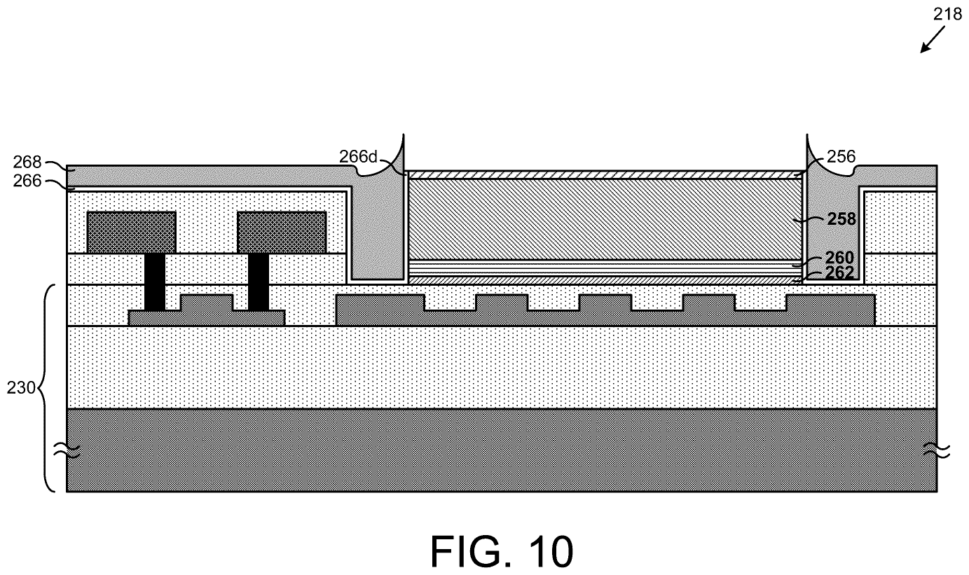

FIG. 1A illustrates a portion of a flowchart of an exemplary method for manufacturing a semiconductor structure according to one implementation of the present application. Structures shown in FIGS. 2A through 8 illustrate the results of performing actions 102 through 114 shown in flowchart 100A of FIG. 1A. For example, FIG. 2A shows a semiconductor structure after performing action 102 in FIG. 1A, FIG. 3 shows a semiconductor structure after performing action 104 in FIG. 1A, FIG. 4A shows a semiconductor structure after performing action 106 in FIG. 1A, and so forth. FIG. 1B illustrates a portion of a flowchart of an exemplary method for manufacturing a semiconductor structure, as a continuation to flowchart 100A of FIG. 1A, according to one implementation of the present application. Structures shown in FIGS. 9 through 15 illustrate the results of performing actions 116 through 128 shown in flowchart 100B of FIG. 1B. For example, FIG. 9 shows a semiconductor structure after performing action 116 in FIG. 1B, FIG. 10 shows a semiconductor structure after performing action 118 in FIG. 1B, and so forth.

Actions 102 through 128 shown in flowcharts 100A and 100B of FIGS. 1A and 1B are sufficient to describe one implementation of the present inventive concepts. Other implementations of the present inventive concepts may utilize actions different from those shown in flowcharts 100A and 100B of FIGS. 1A and 1B. Certain details and features have been left out of the flowcharts that are apparent to a person of ordinary skill in the art. For example, an action may consist of one or more sub-actions or may involve specialized equipment or materials, as known in the art. Moreover, some actions, such as masking and cleaning actions, may be omitted so as not to distract from the illustrated actions.

FIG. 2A illustrates a layout of a semiconductor structure processed in accordance with action 102 in flowchart 100A of FIG. 1A according to one implementation of the present application. As shown in FIG. 2A, in semiconductor structure 202A, substrate 230 is provided.

Substrate 230 includes multiple integrated circuits (ICs) 232. In one implementation, substrate 230 is a group IV substrate. As used herein, the phrase “group IV” refers to a semiconductor material that includes at least one group IV element such as silicon (Si), germanium (Ge), and carbon (C), and may also include compound semiconductors such as silicon germanium (SiGe) and silicon carbide (SiC), for example. “Group IV” also refers to semiconductor materials that include more than one layer of group IV elements, or doping of group IV elements to produce strained group IV materials, and may also include group IV based composite substrates such as silicon on insulator substrates, separation by implantation of oxygen (SIMOX) process substrates, and silicon on sapphire (SOS) substrates, for example. In one implementation, substrate 230 is a semiconductor-on-insulator (SOI) wafer having a diameter of approximately two hundred millimeters (200 mm). In various implementations, substrate 230 can be glass, quartz, or sapphire.

In various implementations, substrate 230 can include greater or fewer ICs 232 than those shown in FIG. 2A. In the present implementation, ICs 232 have an approximately square shape. In one implementation, each of ICs 232 has dimensions of approximately twenty microns by approximately twenty microns (20 μm×20 μm). In various implementations, ICs 232 can have any other shapes and/or arrangements in substrate 230. As described below, each of ICs 232 can include devices, such as group IV devices (not shown in FIG. 2A).

FIG. 2B illustrates a cross-sectional view of a portion of a semiconductor structure corresponding to FIG. 2A processed in accordance with action 102 in the flowchart of FIG. 1A according to one implementation of the present application. The cross-sectional view in FIG. 2B generally corresponds to a portion of one of ICs 232 in FIG. 2A. As shown in FIG. 2B, in semiconductor structure 202B, substrate 230 is provided.

Semiconductor structure 202B includes substrate 230 having handle wafer 234, buried oxide (BOX) 236, semiconductor layer 238, and dielectric 240. In the present implementation, substrate 230 is a semiconductor-on-insulator (SOI) substrate. In providing substrate 230, a bonded and etch back SOI (BESOI) process can be used, as known in the art. Alternatively, as also known in the art, a SIMOX process or a “smart cut” process can also be used for providing substrate 230. In various implementations, substrate 230 may be another type of substrate other than an SOI substrate.

In one implementation, handle wafer 234 is undoped bulk silicon. In various implementations, handle wafer 234 can comprise germanium, group III-V material, or any other suitable handle material. In various implementations, handle wafer 234 has a thickness of approximately seven hundred microns (700 μm) or greater or less. In one implementation, a trap rich layer can be situated between handle wafer 234 and BOX 236. In various implementations, BOX 236 typically comprises silicon dioxide (SiO₂), but it may also comprise silicon nitride (Si_{X}N_{Y}), or another insulator material. In various implementations, BOX 236 has a thickness of approximately one micron (1μm) to approximately three microns (3μm) or greater or less. In one implementation, semiconductor layer 238 includes monocrystalline silicon. In various implementations, semiconductor layer 238 can comprise germanium, group III-V material, or any other semiconductor material. In various implementations, semiconductor layer 238 has a thickness of approximately three hundred nanometers (200 nm) to approximately five hundred nanometers (500 nm) or greater or less.

Semiconductor layer 238 includes devices 238a and 238b. Devices 238a and 238b can be any photonics or optoelectronics devices configured to generate, receive, transmit, or modify light. In various implementations, devices 238a and 238b can include a waveguide, a modulator, a grating coupler, an interferometer, a photodiode, or a phototransistor. For example, device 238a can be a modulator, and device 238b can be a grating coupler. Devices 238a and 238b can be formed, for example, by patterning, doping, and/or performing other processing on semiconductor layer 238 of substrate 230. In various implementations, semiconductor layer 238 can include other devices (not shown in FIG. 2B), such as a transistor, an operational amplifier, a driver, a filter, a mixer, or a diode.

Dielectric 240 is situated over semiconductor layer 238 and BOX 236. Dielectric 240 insulates devices 238a and 238b, and aids subsequent processing. In various implementations, dielectric 240 can comprise borophosphosilicate glass (BPSG), tetra-ethyl ortho-silicate (TEOS), SiO₂, Si_{X}N_{Y}, silicon oxynitride (Si_{X}O_{Y}N_{Z}), or another dielectric. Dielectric 240 can be formed by depositing and planarizing a dielectric layer. In one implementation, a thickness of dielectric 240 has a thickness above semiconductor layer 238 of approximately forty nanometers (40 nm) to approximately seventy five nanometers (75 nm) or greater or less.

FIG. 3 illustrates a cross-sectional view of a portion of a semiconductor structure processed in accordance with action 104 in flowchart 100A of FIG. 1A according to one implementation of the present application. As shown in FIG. 3, in semiconductor structure 204, bonding window 250 is formed in interlayer dielectrics 242 and 248 over substrate 230.

Semiconductor structure 204 includes interlayer dielectric 242, contacts 244a and 244b, interconnect metal layer 246 having interconnect metal segments 246a and 246b, interlayer dielectric 248, and bonding window 250. Interlayer dielectric 242 is formed over substrate 230. Interlayer dielectric 242 separates semiconductor layer 238 from interconnect metal layer 246. In various implementations, interlayer dielectric 242 can comprise SiO₂, Si_{X}N_{Y}, or Si_{X}O_{Y}N_{Z}. Interlayer dielectric 242 can be formed in a similar manner to dielectric 240, as described above. Although interlayer dielectric 242 is illustrated as a single dielectric layer in FIG. 3, an interlayer dielectric can be a combination of multiple dielectric layers.

Contacts 244a and 244b are situated in interlayer dielectric 242 and dielectric 240. Contacts 244a and 244b connect device 238a in semiconductor layer 238 to interconnect metal segments 246a and 246b, respectively, in interconnect metal layer 246. In one implementation, contact holes are etched in interlayer dielectric 242 and dielectric 240 over device 238a, a metal is deposited in the contact holes, and then the metal is planarized with interlayer dielectric 242, for example, using chemical mechanical polishing (CMP), thereby forming contacts 244a and 244b. In an alternative implementation, a damascene process is used to form contacts 244a and 244b. In various implementations, contacts 244a and 244b can comprise tungsten (W), copper (Cu), or aluminum (Al). In various implementations, a metal liner can be situated between contacts 244a and 244b and device 238a.

Interconnect metal layer 246 is provided over interlayer dielectric 242. Interconnect metal layer 246 includes interconnect metal segments 246a and 246b electrically coupled to contacts 244a and 244b respectively. In one implementation, a metal layer is deposited over interlayer dielectric 242 and contacts 244a and 244b, and then segments thereof are etched, thereby forming interconnect metal segments 246a and 246b. In an alternative implementation, a damascene process is used to form interconnect metal segments 246a and 246b. In various implementations, interconnect metal segments 246a and 246b can comprise W, Al, or Cu.

Contacts 244a and 244b and interconnect metal segments 246a and 246b together route electricity to/from device 238a, which can be, for example, a silicon Mach-Zehnder modulator. Although contacts 244a and 244b and interconnect metal segments 246a and 246b are illustrated as separate formations in FIG. 3, in other implementations they may be parts of the same formation. Semiconductor structure 204 can include other contacts and other interconnect metal segments not shown in FIG. 3. Interconnect metal segments 246a and 246b are situated in and under interlayer dielectric 248. Interlayer dielectric 248 can be formed in a similar manner to interlayer dielectric 242, as described above.

As shown in FIG. 3, bonding window 250 is formed in interlayer dielectrics 242 and 248. Bonding window 250 can be formed by patterning a lithographic mask on interlayer dielectric 248 to have an opening overlying device 238b, then etching through interlayer dielectrics 242 and 248 to dielectric 240 using, for example, reactive ion etching (RIE). In one implementation, a sacrificial etch stop (not shown) over dielectric 240 prevents etching of dielectric 240 and/or semiconductor layer 238. In such implementation, the sacrificial etch stop can be removed using a wet etch that is selective to the material of the sacrificial etch stop, such as a phosphoric acid wet etch selective to Si_{X}N_{Y}.

FIG. 4A illustrates a layout of a semiconductor structure processed in accordance with action 106 in flowchart 100A of FIG. 1A according to one implementation of the present application. As shown in FIG. 4A, in semiconductor structure 206A, chiplets 252 are bonded to substrate 230.

Chiplets 252 are unpatterned dies. Chiplets 252 can be provided by forming multiple layers on a substrate, as described below, and then dicing the substrate and the layers into chiplets 252. In one implementation, chiplets 252 can be formed from an InP wafer having a diameter of approximately one hundred millimeters (100 mm). In the present implementation, one of chiplets 252 is bonded to each IC 232. In other implementations, more or fewer chiplets 252 can be bonded to each IC 232.

In one implementation, chiplets 252 are group III-V chiplets. As used herein, the phrase “group III-V” refers to a compound semiconductor including at least one group III element, such as indium (In), gallium (Ga), aluminum (Al), and boron (B), and at least one group V element, such as arsenic (As), phosphorus (P), and nitrogen (N). By way of example, a group III-V semiconductor may take the form of indium phosphide (InP). “Group III-V” can also refer to a compound semiconductor that includes an alloy of a group III element and/or an alloy of a group V element, such as indium gallium arsenide (In_{X}Ga_{1-X}As), indium gallium nitride (In_{X}Ga_{1-X}N), aluminum gallium nitride (Al_{X}Ga_{1-X}N), aluminum indium gallium nitride (Al_{X}In_{Y}Ga_{1-X-Y}N), gallium arsenide phosphide nitride (GaAs_{A}P_{B}N_{1-A-B}), and aluminum indium gallium arsenide phosphide nitride (Al_{X}In_{Y}Ga_{1-X-Y}As_{A}P_{B}N_{1-A-B}), for example. “Group III-V” also refers generally to any polarity including but not limited to Ga-polar, N-polar, semi-polar, or non-polar crystal orientations. A group III-V material may also include either the Wurtzitic, Zincblende, or mixed polytypes, and may include single-crystal, monocrystalline, polycrystalline, or amorphous structures.

In various implementations, chiplets 252 can comprise lithium niobate (LiNbO₃), lithium tantalate (LiTa), potassium dihydrogen phosphate (KDP), deuterated potassium dihydrogen phosphate (DKDP), rubidium titanyl phosphate (RTP), potassium titanyl phosphate (KTP), potassium titanyl arsenate (KTA), barium borate (BBO), barium titanate (BTO), ammonium dihydrogen phosphate (ADP), cadmium telluride (CdTe), organic materials which demonstrate a strong Pockels effect, or any other suitable Pockels material.

FIG. 4B illustrates a cross-sectional view of a portion of a semiconductor structure corresponding to FIG. 4A processed in accordance with action 106 in flowchart 100A of FIG. 1A according to one implementation of the present application. The cross-sectional view in FIG. 4B generally corresponds to a portion of one of ICs 232 in FIG. 4A. As shown in FIG. 4B, in semiconductor structure 206B, chiplet 252 is bonded to substrate 230 in bonding window 250. Chiplet 252 includes bulk layer 254, etch stop layer 256, and active layers 258, 260, and 262.

Chiplet 252 can be formed by sequentially depositing etch stop layer 256 and active layers 258, 260, and 262 over bulk layer 254 used as a substrate. Chiplet 252 can be flipped relative to the orientation it was formed, such that bulk layer 254 is on the top and active layer 262 is on the bottom. Then chiplet 252 is bonded to substrate 230 in bonding window 250. Bulk layer 254 supports active layers 258, 260, and/or 262 during the bonding action. Chiplet 252 can be bonded using any suitable bonding technique. Where a device subsequently formed from active layers 258, 260, and/or 262 is configured to interact with device 238b, chiplet 252can be bonded without using an adhesive that could interfere with such interaction. In one implementation, chiplet 252 is bonded in bonding window 250 using fusion bonding by contacting active layer 262 and dielectric 240, then applying heat and/or pressure. Chiplet 252 can be bonded to substrate 230 by oxygen plasma assisted direct bonding, whereby the surfaces of chiplet 252 and substrate 230 can be cleaned, then activated by an oxygen plasma, then placed in physical contact at room temperature to bond. In one implementation, after bonding, a low-temperature anneal can also be performed. For example, semiconductor structure 206B can be annealed at a temperature of approximately three hundred degrees Celsius (300° C.).

After the bonding action, chiplet 252 is situated in bonding window 250. Gap 264 is situated in bonding window 250 between chiplet 252 and sidewalls 243 and 249 of interlayer dielectrics 242 and 248. In semiconductor structure 206B, chiplet 252 is shown to overlie device 238b. In other implementations, chiplet 252 may overlie more or fewer devices of substrate 230. For example, devices can be situated in an area of IC 232 (shown in FIG. 4A) that does not underlie chiplet 252.

Chiplet 252 represents an unpatterned die, suitable for patterning into a device. In one implementation, chiplet 252 is suitable or patterning into an optoelectronic device, such as a laser, a photodiode, or an electro-absorption modulator (EAM). For example, active layers 258 and 262 can function as a P type anode and an N type cathode, respectively, of a group III-V photodiode. In one implementation, the dopant types can be switched (i.e., N type doped active layer 258 and P type doped active layer 262). In other implementations, chiplet 252 can have other layering and/or doping suitable for other devices. Chiplet 252 may include more or fewer active layers than shown in FIG. 4B. In other implementations, some patterning may be performed prior to bonding.

In various implementations, bulk layer 254 can be an InP substrate having a thickness of approximately forty microns (40 μm) to approximately one hundred microns (100 μm) or greater or less. In various implementations, etch stop layer 256 can comprise AlGaAs having a thickness of approximately one hundred nanometers (100 nm) or greater or less. In one example, active layers 258, 260, and 262 form a P-I-N junction, and chiplet 252 is suitable for patterning into an optoelectronic device. In this example, active layer 258 can comprise GaAs implanted with boron or another appropriate P type dopant. In various implementations, active layer 258 has a thickness of approximately two microns (2 μm) or greater or less. As known in the art, active layer 258 can comprise a thin heavily doped contact layer near bulk layer 254 and a thick lightly doped cladding layer near active layer 260. In various implementations, active layer 258 can include other group III-V materials instead of or in addition to GaAs.

Continuing the above example, active layer 260 can comprise several undoped transitional layers, such as InGaAs layers each having a thickness of approximately ten nanometers (10 nm). These transition layers can function as quantum wells to provide optical gain. As known in the art, active layer 260 can also comprise confinement layers around the quantum wells and having lower refractive index. In various implementations, active layer 260 has a combined thickness of approximately two hundred nanometers (200 nm) to approximately four hundred nanometers (400 nm) or greater or less. In various implementations, active layer 260 can include other group III-V materials instead of or in addition to InGaAs.

Continuing the above example, active layer 262 can be a group III-V layer having an opposite doping type than active layer 258. Active layer 262 can comprises GaAs implanted with phosphorus or another appropriate N type dopant. In various implementations, active layer 262 has a thickness of approximately one hundred and fifty nanometers (150 nm) or greater or less. In various implementations, active layer 262 can include other group III-V materials instead of or in addition to GaAs.

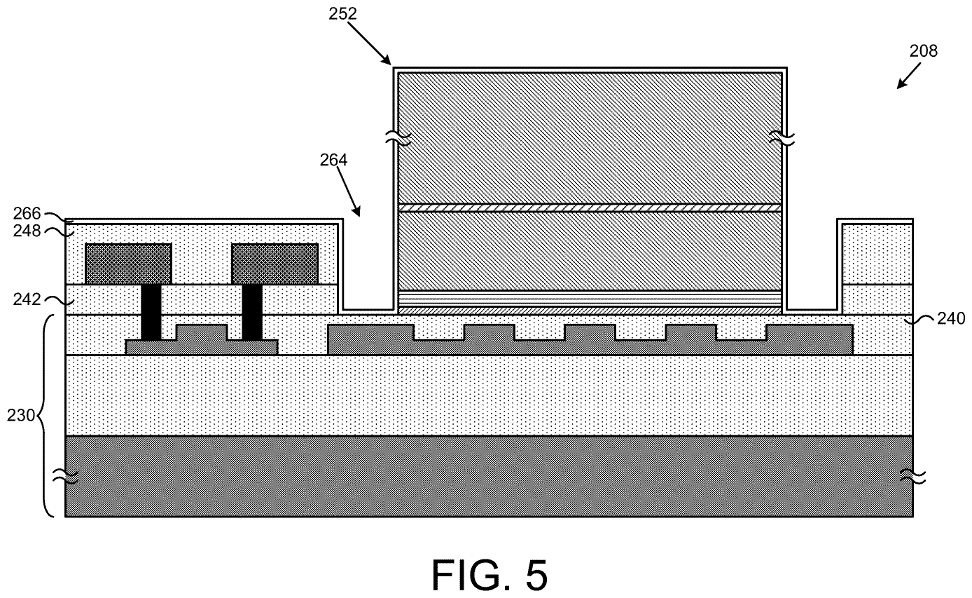

FIG. 5 illustrates a cross-sectional view of a portion of a semiconductor structure processed in accordance with action 108 in flowchart 100A of FIG. 1A according to one implementation of the present application. As shown in FIG. 5, in semiconductor structure 208, hardmask 266 is formed over chiplet 252.

In particular, hardmask 266 is formed in gap 264 on dielectric 240 of substrate 230, over interlayer dielectric 248, against sidewalls of interlayer dielectrics 242 and 248, against sidewalls of chiplet 252, and over chiplet 252. In one implementation, hardmask 266 can comprise a nitride, such as Si_{X}N_{Y} or Si_{X}O_{Y}N_{Z}. In other implementations hardmask 266 can comprise another dielectric. Hardmask 266 can be formed, for example, by plasma enhanced chemical vapor deposition (PECVD) or high density plasma CVD (HDP-CVD). Notably, although the exact topography of hardmask 266 will depend on the formation process used, the topography of hardmask 266 generally mirrors that of chiplet 252 and interlayer dielectric 248. In various implementations, a deposition thickness of hardmask 266 can be approximately fifty nanometers (50 nm) or greater or less.

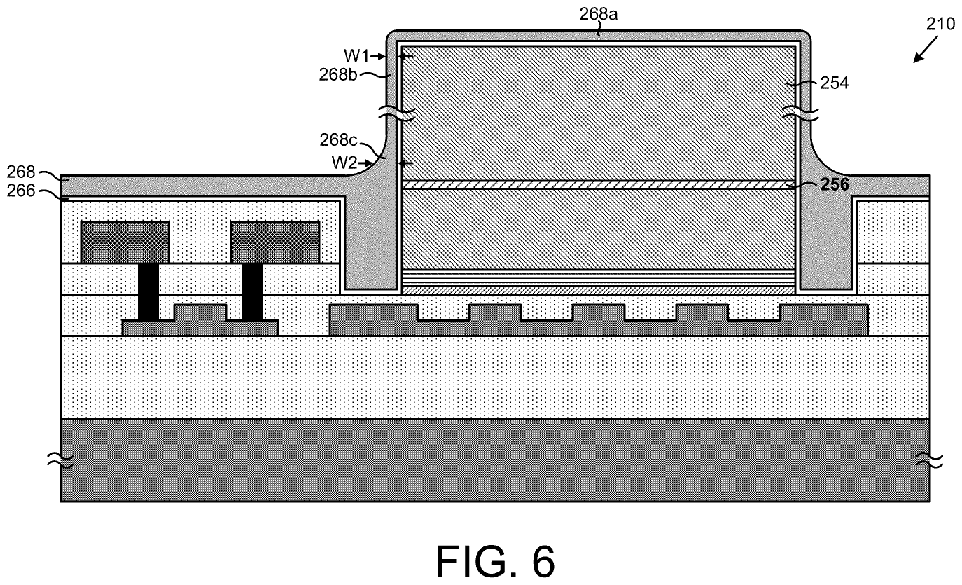

FIG. 6 illustrates a cross-sectional view of a portion of a semiconductor structure processed in accordance with action 110 in flowchart 100A of FIG. 1A according to one implementation of the present application. As shown in FIG. 6, in semiconductor structure 210, photoresist 268 is formed over hardmask 266.

Photoresist 268 includes photoresist segments 268a, 268b, and 268c. Photoresist segment 268a is situated over bulk layer 254. Photoresist segment 268b is an upper photoresist segment along the sidewall of bulk layer 254, closer to the top surface of bulk layer 254. Photoresist segment 268c is a lower photoresist segment along the sidewall of bulk layer 254, closer to the bottom surface of bulk layer 254. Upper photoresist segment 268b has a lesser width W1 along the sidewall of bulk layer 254. Lower photoresist segment 268c has a greater width W2 along the sidewall of bulk layer 254. In other words, photoresist 268 is wider along the lower portion of bulk layer 254 near etch stop layer 256. Photoresist 268 can comprise any photoresist material known in the art, such as SU-8. Photoresist 268 can be formed using any technique known in the art, such as spin coating.

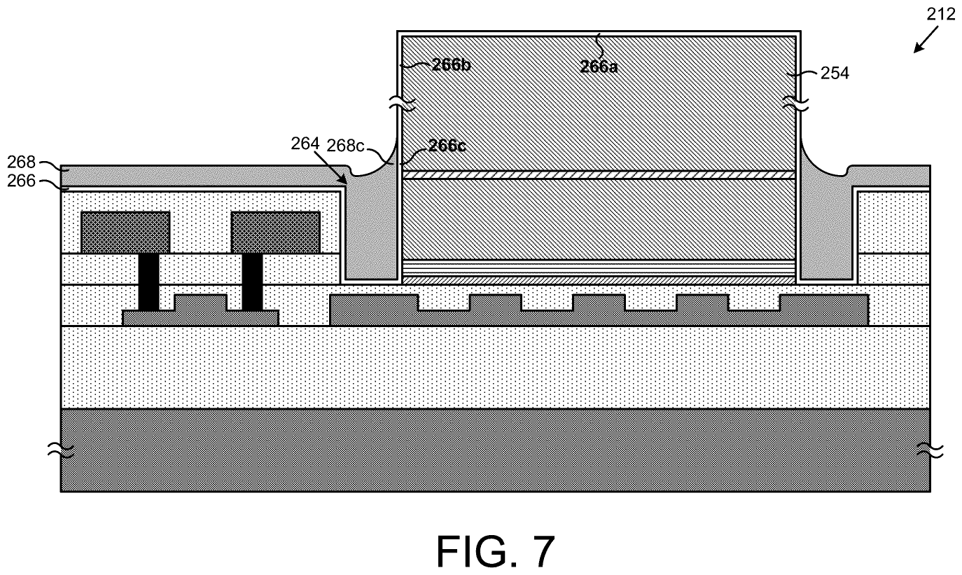

FIG. 7 illustrates a cross-sectional view of a portion of a semiconductor structure processed in accordance with action 112 in flowchart 100A of FIG. 1A according to one implementation of the present application. As shown in FIG. 7, in semiconductor structure 212, photoresist segments 268a and 268b (shown in FIG. 6) of photoresist 268 are removed to expose respective hardmask segments 266a and 266b of hardmask 266.

After removing photoresist segments 268a and 268b, lower photoresist segment 268c along the sidewall of bulk layer 254 remains, and corresponding lower hardmask segment 266c against the sidewall of bulk layer 254 is not exposed. Photoresist segments 268a and 268b can be removed by selectively exposing photoresist 268 to light using a patterned mask and then applying a developer to remove exposed portion. In one implementation, the patterned mask be configured to have an opening that is wider than the width of bulk layer 254 and extends over gap 264, in order to assist in removing upper photoresist segment 268b along the sidewall of bulk layer 243. In one implementation, light can be incident on photoresist 268 at an angle other than normal to the top surface of bulk layer 254, in order to assist in removing upper photoresist segment 268b while preserving some of lower photoresist segment 268c. The removal may thin portions of photoresist 268 in and/over gap 264.

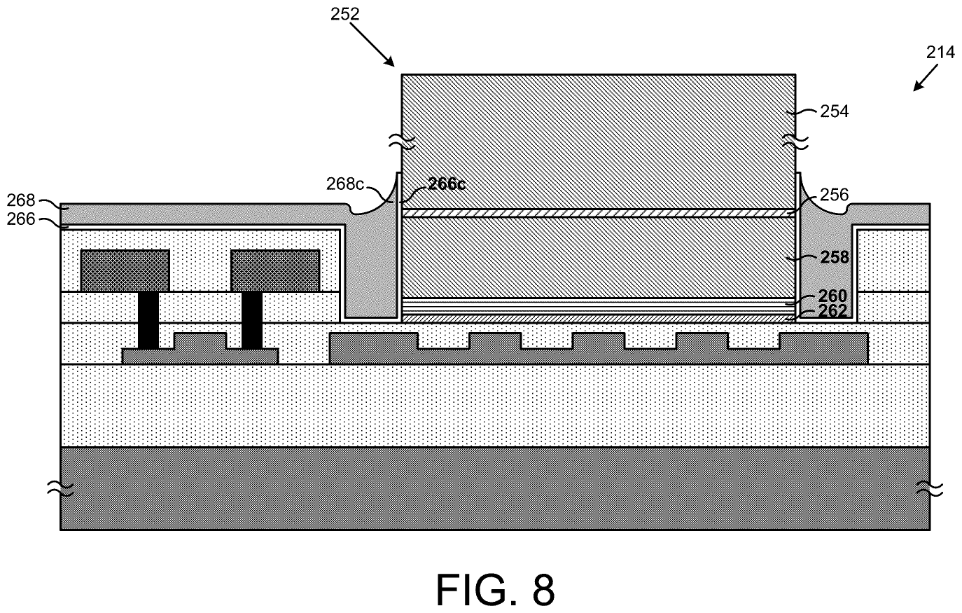

FIG. 8 illustrates a cross-sectional view of a portion of a semiconductor structure processed in accordance with action 114 in flowchart 100A of FIG. 1A according to one implementation of the present application. As shown in FIG. 8, in semiconductor structure 214, hardmask segments 266a and 266b (shown in FIG. 7) of hardmask 266 are removed to expose bulk layer 254 without exposing active layers 258, 260, and 262.

Removing hardmask segments 266a and 266b exposes the top surface and an upper portion of the sidewall of bulk layer 254. The remainder of chiplet 252, including a lower portion of bulk layer 254 and all of etch stop layer 256 and active layers 258, 260, and 262 remain unexposed, covered with hardmask 266 and photoresist 268. Lower hardmask segment 266c covered with lower photoresist segment 268c is situated higher than the top surfaces of active layer 258 and etch stop layer 256. Hardmask segments 266a and 266b can be removed, for example, using a wet etch process.

FIG. 9 illustrates a cross-sectional view of a portion of a semiconductor structure processed in accordance with action 116 in flowchart 100B of FIG. 1B according to one implementation of the present application. As shown in FIG. 9, in semiconductor structure 216, bulk layer 254 of chiplet 252 (shown in FIG. 8) is removed.

Bulk layer 254 can be removed, for example, using a wet etch process. Etch stop layer 256 protects active layer 258 during the removal of bulk layer 254. Etch stop layer 256 can be configured as an etch stop for lower active layer 258. Etch stop layer 256 along with hardmask 266 encapsulates active layer 258, and when bulk layer 254 is removed by etching, etch stop layer 256 is a different material than bulk layer 254 that has significantly lower etch rate, such that the etching is selective to bulk layer 254. For example, where bulk layer 254 is InP and is removed by hydrochloric (HCl) wet etch, etch stop layer 256 can be AlGaAs.

In the present implementation, after removing bulk layer 254, etch stop layer 256 can remain in semiconductor structure 216 as an active layer. For example, etch stop etch stop layer 256 can be an active group III-V layer, such as P type AlGaAs, suitable for patterning into an optoelectronic device. In other implementations, etch stop layer 256 can be a sacrificial layer removed after removing bulk layer 254.

FIG. 10 illustrates a cross-sectional view of a portion of a semiconductor structure processed in accordance with action 118 in flowchart 100B of FIG. 1B according to one implementation of the present application. As shown in FIG. 10, in semiconductor structure 218, hardmask segment 266c (shown in FIG. 9) situated higher than active layer 256 (where etch stop 256 is an active layer) is removed. Hardmask segment 266c can be removed, for example, using an isotropic plasma etch process. Photoresist 268 and active layer 256 can protect semiconductor structure 218 during removal of hardmask segment 266c.

As shown in FIG. 10, hardmask segment 266d of hardmask 266 remains against sidewalls of active layers 256, 258, 260, and 262. The top of hardmask segment 266d is at approximately the same height as the top surface of active layer 256. As used herein, “at approximately the same height” refers to being at the same level or the same distance normal to substrate 230, except for normal process variations associated with removal of higher portions. For example, where removing hardmask segment 266c utilizes an isotropic etch that etches equally in all directions, the top of hardmask segment 266d may be lower than the top surface of active layer 256 by approximately the thickness of hardmask 266, which can be approximately fifty nanometers (50 nm).

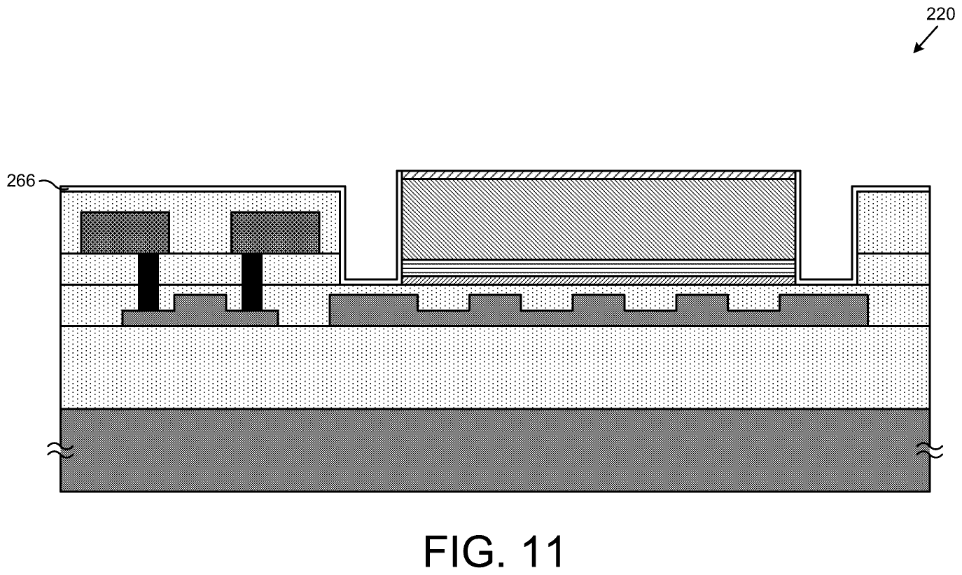

FIG. 11 illustrates a cross-sectional view of a portion of a semiconductor structure processed in accordance with action 120 in flowchart 100B of FIG. 1B according to one implementation of the present application. As shown in FIG. 11, in semiconductor structure 220, a remainder of photoresist 268 (shown in FIG. 10) is removed from over hardmask 266. The remainder of photoresist 268 (that is, what remained after removal action 112 of FIG. 1A, shown in FIG. 7) can be removed using any technique known in the art, such as chemical stripping.

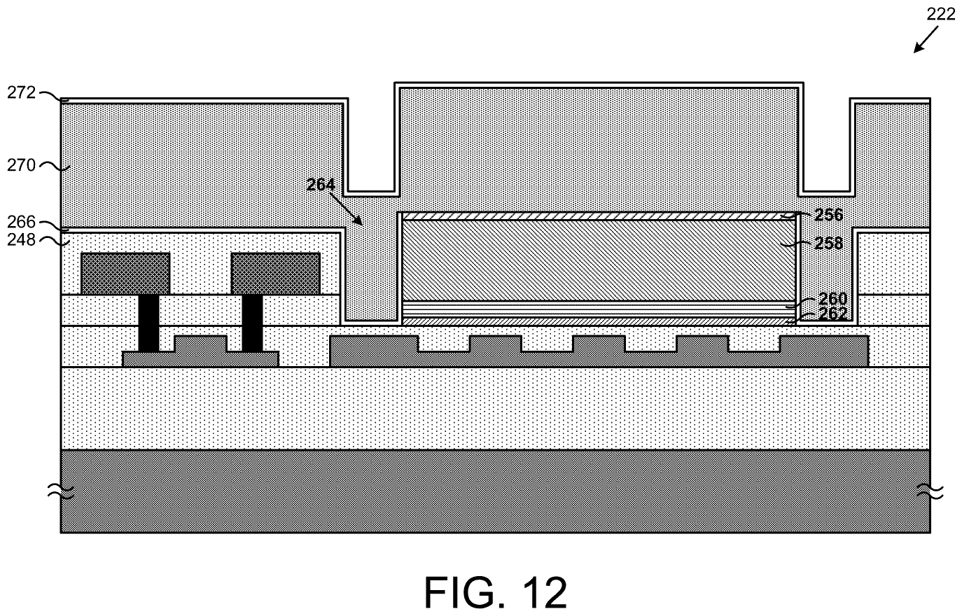

FIG. 12 illustrates a cross-sectional view of a portion of a semiconductor structure processed in accordance with action 122 in flowchart 100B of FIG. 1B according to one implementation of the present application. As shown in FIG. 12, in semiconductor structure 222, blanket dielectrics 270 and 272 are formed over active layer 256 and hardmask 266.

Blanket dielectric 270 is situated on hardmask 266 in gap 264 and on hardmask 266 over interlayer dielectric 248. Blanket dielectric 270 is also situated over active layers 256, 258, 260, and 262. Blanket dielectric 272 is situated on blanket dielectric 270. Blanket dielectrics 270 and 272 include portions over active layer 256 in a region where bulk layer 254 (shown in FIG. 8) was removed. In the present implementation, the combined thickness of blanket dielectric 270 and hardmask 266 is greater than the combined thickness of active layers 256, 258, 260, and 262, such that blanket dielectric 270 is situated higher than top active layer 256 across the wafer, including over gap 264.

Blanket dielectrics 270 and 272 can be formed, for example, by PECVD or HDP-CVD. Notably, the topography of blanket dielectrics 270 and 272 generally mirrors that of active layer 256 and hardmask 266. In one implementation, blanket dielectric 270 can comprise an oxide, such as SiO₂, and blanket dielectric 272 can comprise a nitride, such as Si_{X}N_{Y} or Si_{X}O_{Y}N_{Z}. In various implementations, deposition thicknesses of blanket dielectrics 270 and 272 can be approximately three microns (3 μm) and approximately one half micron (0.5 μm), respectively, or greater or less. In various implementations, semiconductor structure 222 can include more or fewer blanket dielectrics than shown in FIG. 12.

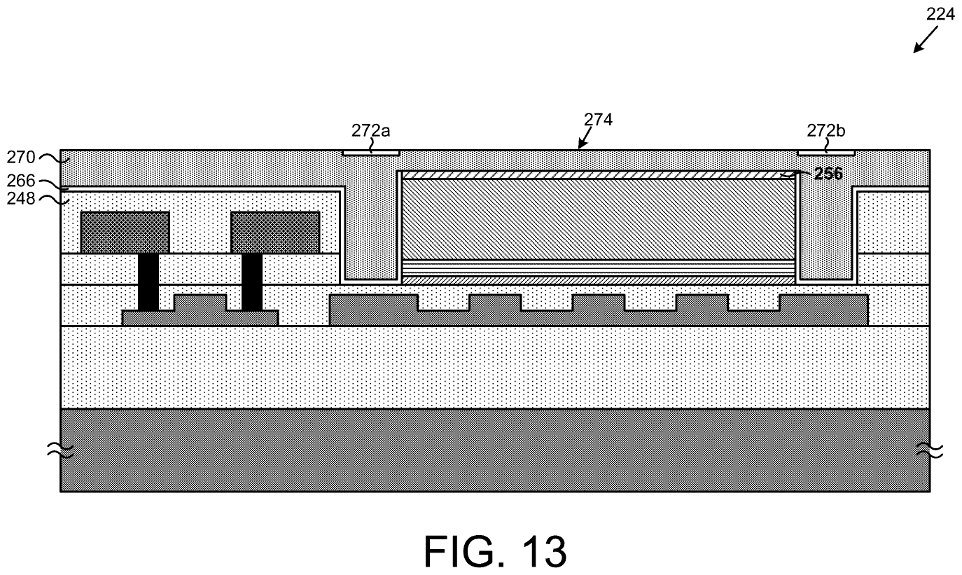

FIG. 13 illustrates a cross-sectional view of a portion of a semiconductor structure processed in accordance with action 124 in flowchart 100B of FIG. 1B according to one implementation of the present application. As shown in FIG. 13, in semiconductor structure 224, blanket dielectrics 270 and 272 are planarized.

Blanket dielectrics 270 and 272 can be planarized, for example, using CMP. The planarizing action shown between FIGS. 12 and 13 removes relatively large peaks of blanket dielectrics 270 and 272 that were over active layer 256 and interlayer dielectric 248. Planarizing separates blanket dielectric 272 into blanket dielectric segments 272a and 272b. After planarizing, blanket dielectric 270 and blanket dielectric segments 272a and 272b form a top surface 274 that is substantially planar over both active layer 256 and hardmask 266. As used herein, “substantially planar” refers to a surface being planar, except for normal dishing and other normal process variations associated with planarization.

In the present implementation, blanket dielectric 272 (shown in FIG. 12) is configured as a planarization stop layer. For example, when blanket dielectrics 270 and 272 are planarized by CMP, blanket dielectric 272 can be a different material than blanket dielectric 270 that has significantly lower etch rate. The horizontal surfaces of blanket dielectric 272 can have relatively large surface area parallel to the polishing plane compared to the vertical surfaces of blanket dielectric 272 (note that gap 264 and blanket dielectric 272 thereover shown in FIG. 12 are not necessarily drawn to scale, and may be significantly wider). Accordingly, the planarization process can be easily stopped upon reaching the bottom of blanket dielectric 272, that is, upon reaching blanket dielectric segments 272a and 272b in FIG. 13.

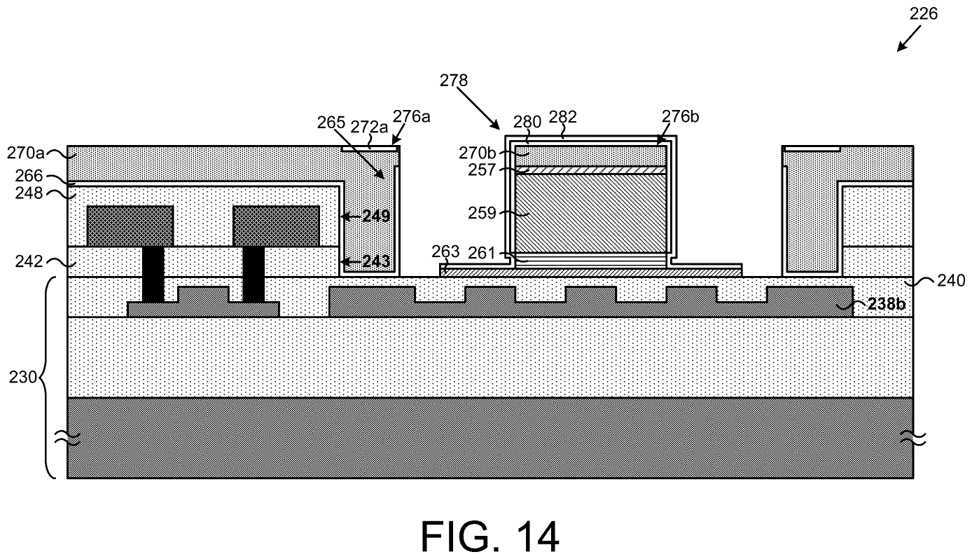

FIG. 14 illustrates a cross-sectional view of a portion of a semiconductor structure processed in accordance with action 126 in flowchart 100B of FIG. 1B according to one implementation of the present application. As shown in FIG. 14, in semiconductor structure 226, device 278 is formed from active layers 256, 258, 260, and 262 (shown in FIG. 13).

Device 278 can be formed from active layers 256, 258, 260, and 262 by patterning them into respective active layers 257, 259, 261, and 263. Device 278 can be formed by depositing and patterning a hardmask over blanket dielectrics 270 and 272, then etching through blanket dielectric 270, through active layer 256, and into active layer 258 using an inductively coupled plasma (ICP) etch. This can separate blanket dielectric 270 into blanket dielectric segments 270a and 270b, and separate top surface 274 into top surfaces 276a and 276b. Then active layer 258 can be etched through using a wet etch. In this implementation, active layer 258 may be selectively etched while active layer 260 performs as an etch stop. Then protective layer 280 can be formed on the top and an upper portion of the side of the structure. Then active layer 260 can be etched, for example, using a reactive ion etch (RIE) and/or a wet etch. Then protective layer 282 can be formed over the structure leaving a portion of active layer 262 exposed. Finally, active layer 262 can be etched through using a wet etch. In various implementations, protective layers 280 and 282 can comprise Si_{X}N_{Y} or Si_{X}O_{Y}N_{Z}.

Patterning active layers 257, 259, 261, and 263 extends the gap in the bonding window. That is, gap 265 (shown in FIG. 14) between device 278 and sidewalls 243 and 249 of interlayer dielectrics 242 and 248 is bigger than gap 264 (shown in FIG. 4B) between chiplet 252 and sidewalls 243 and 249. Blanket dielectric segments 270a and 272a are on hardmask 266 over interlayer dielectric 248, and on hardmask 266 in a portion of gap 265. Top surface 276a of blanket dielectric segments 270a and 272a is substantially planar and situated higher than the top surfaces of active layers 257 and 259. Top surfaces 276a and 276b are substantially planar and at approximately the same height, separated by a portion of gap 265.

In one implementation, device 278 is an optoelectronic device, such as a laser, a photodiode, or an EAM. For example, active layers 257 and/or 259 can function as a P type anode of a group III-V photodiode, and active layer 263 can function as an N type cathode of the group III-V photodiode. Device 278 is bonded to dielectric 240 of substrate 230. Device 278 is optically connected to device 238b in substrate 230. Device 278 is approximately aligned with device 238b. Device 278 is separated from device 238b by a thin portion of dielectric 240 that was used to protect devices 238a and 238b during bonding action 106 (shown in FIG. 4B). As described above, in various implementations, device 238b can be a waveguide, grating coupler, or an interferometer. In one implementation, device 238b may couple light to/from device 278 from/to another plane not visible in the cross-sectional view of FIG. 14. In another implementation, device 238b may couple light to/from patterned device 278 from/to a bottom of substrate 230. In various implementations, device 278 can be optically connected to additional devices (not shown in FIG. 14) in substrate 230. Similarly, devices 238a and 238b can be optically connected to additional devices (not shown in FIG. 14) in substrate 230 and/or to an optical input/output interface (not shown in FIG. 14).

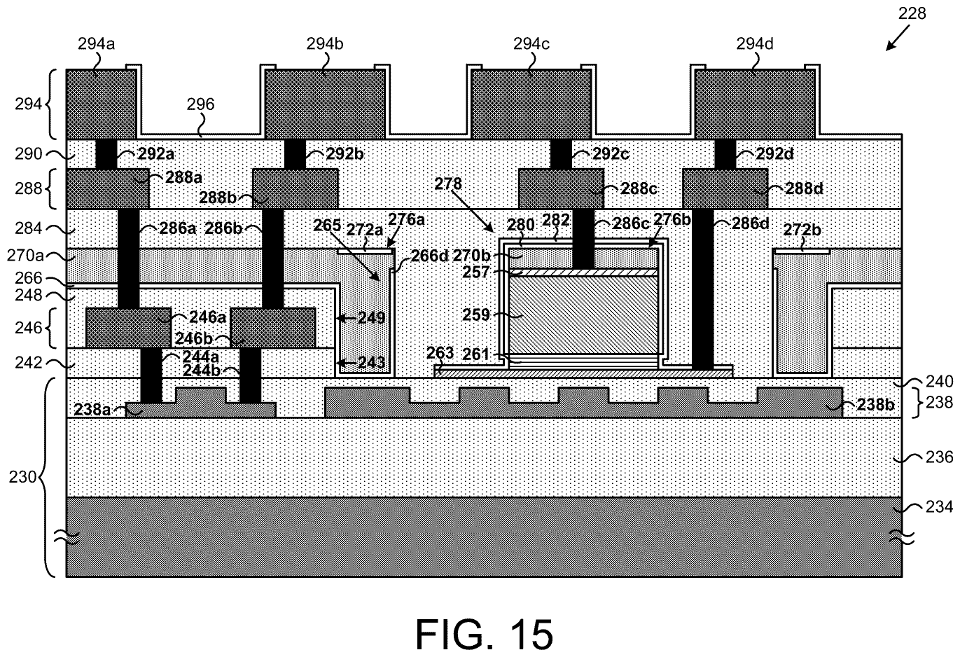

FIG. 15 illustrates a cross-sectional view of a portion of a semiconductor structure processed in accordance with action 128 in flowchart 100B of FIG. 1B according to one implementation of the present application. As shown in FIG. 15, in semiconductor structure 228, additional processing is completed. The additional processing includes forming interlayer dielectric 284, vias 286a and 286b, contacts 286c and 286d, interconnect metal layer 288, interconnect metal segments 288a, 288b, 288c, and 288d, interlayer dielectric 290, vias 292a, 292b, 292c, and 292d, interconnect metal layer 294, interconnect metal segments 294a, 294b, 294c, and 294d, and passivation layer 296.

Interlayer dielectric 284 is formed over blanket dielectrics 270a and 272a, in a portion of gap 265 over dielectric 240 and active layer 263, and over active layers 257, 259, and 260 of device 278. Blanket dielectrics 270a and 272a are under interlayer dielectric 284 and over hardmask 266. Hardmask segment 266d is in gap 265 between blanket dielectric 270a and interlayer dielectric 284. Blanket dielectric 270b and protective layers 280 and 282 are under interlayer dielectric 284. Interlayer dielectric 284 can be formed in a similar manner to interlayer dielectrics 242 and 248, as described above.

Vias 286a and 286b are situated in interlayer dielectric 284, blanket dielectric 270a, hardmask 266, and interlayer dielectric 248. Vias 286a and 286b connect interconnect metal segments 246a and 246b in interconnect metal layer 246 to interconnect metal segments 288a and 288b, respectively, in interconnect metal layer 288. Contact 286c is situated in interlayer dielectric 284, protective layers 280 and 282, and blanket dielectric 270b. Contact 286d is situated in interlayer dielectric 284 and protective layer 282. Contacts 286c and 286d are connected to device 278 to apply or receive electricity. Contact 286c is connected to active layer 257. Contact 286d is connected to active layer 263. In one implementation, contacts 286c and 286d to device 278 can be formed concurrently with vias 286a and 286b to interconnect metal segments 246a and 246b.

Interconnect metal layer 288 is formed over interlayer dielectric 284. Interconnect metal layer 288 includes interconnect metal segments 288a, 288b, 288c, and 288d electrically coupled to vias and contacts 286a, 286b, 286c, and 286d respectively.

Interconnect metal segments 288a, 288b, 288c, and 288d are situated in and under interlayer dielectric 290. Vias 292a, 292b, 292c, and 292d are situated in interlayer dielectric 290. Vias 292a, 292b, 292c, and 292d connect interconnect metal segments 288a, 288b, 288c, and 288d in interconnect metal layer 288 to interconnect metal segments 294a, 294b, 294c, and 294d, respectively, in interconnect metal layer 294. Interconnect metal layer 294 is formed over interlayer dielectric 290. Interconnect metal layer 294 includes interconnect metal segments 294a, 294b, 294c, and 294d electrically coupled to vias 292a, 292b, 292c, and 292d respectively. Vias 286a, 286b, 292a, 292b, 292c, and 292d, and contacts 286c and 286d can be formed in a similar manner to contacts 238a and 238b, as described above. Interconnect metal segments 288a, 288b, 288c, 288d, 294a, 294b, 294c, and 294d can be formed in a similar manner to interconnect metal segments 240a and 240b, as described above.

Passivation layer 296 is formed over and on sidewalls of interconnect metal segments 294a, 294b, 294c, and 294d, and over interlayer dielectric 290. Passivation layer 290 can be formed by conformal deposition, for example, by physical vapor deposition (PVD) or CVD techniques. In various implementations, passivation layer 296 can include a semiconductor-based dielectric such as Si_{X}O_{Y}, Si_{X}N_{Y}, or Si_{X}O_{Y}N_{Z}. In various implementations, passivation layer 296 can have a thickness of approximately fifty angstroms (50 Å) to approximately two hundred angstroms (200 Å). In various implementations, passivation layer 296 comprises multiple passivation layers. As shown in FIG. 15, windows are formed in passivation layer 296 exposing portions of interconnect metal segments 294a, 294b, 294c, and 294d. Thus, the exposed portions of interconnect metal segments 294a, 294b, 294c, and 294d can function as bond pads for electrical connections external to semiconductor structure 228.

Contacts 244a and 244b, vias 286a, 286b, 292a, and 292b, and interconnect metal segments 246a, 246b, 288a, 288b, 294a, and 294b together route electricity to/from device 238a, which can be, for example, a silicon Mach-Zehnder modulator. Similarly, contacts 286c and 286d, vias 292c and 292d, and interconnect metal segments 288c, 288d, 294c, and 294d together route electricity to/from device 278, which can be, for example, a group III-V photodiode. In various implementations, some contacts, vias, and interconnect metal segment may route to other components in semiconductor structure 228 instead of or in addition to bond pads at interconnect metal layer 294.

It is noted that, although device 278 is formed by patterning chiplet 252 in the present implementation, as shown across FIGS. 13 and 14, in other implementations, such patterning may be omitted. For example, referring to FIG. 13, chiplet 252 may already have appropriate dimensions to perform as an optoelectronic device.

Referring to FIG. 3, it is also noted that, although bonding window 250 is formed in both interlayer dielectrics 242 and 248 after forming contacts 244a and 244b and interconnect metal segments 246a and 246b in the present implementation, other implementations are possible. Namely, device 278 can generally be formed at any level in semiconductor structure 228 in FIG. 15. For example, bonding window 250 in FIG. 3 can be formed in only interlayer dielectric 248 while interlayer dielectric 242 is intact, and chiplet 252 can be bonded and processed before even forming contacts 244a and 244b or interconnect metal segments 246a and 246b. In such implementation, contacts to device 278 may be formed substantially concurrently with contacts to device 238a.

Fabricating semiconductor structures according to the present invention results in several advantages. First, since hardmask segments 266a and 266b (shown in FIG. 7) are removed (as in action 114 of FIG. 1A, shown in FIG. 8), the entire top surface of bulk layer 254, as well as an upper portion of the sidewall of bulk layer 254, are exposed. This enables bulk layer 254 to be removed in a single action (as in action 116 of FIG. 1B, shown in FIG. 9). In contrast, conventional techniques tend to leave residual bulk portions when removing the main portion of a bulk layer. The residual bulk portions require more complex design considerations. More actions are needed to completely remove the bulk layer, increasing fabrication time and cost. Further, forming a device such as device 278 can require starting with a wider chiplet in order to account for the volumes that will form residual bulk portions. The present invention can utilize a narrower chiplet 252, and accordingly, a narrower bonding window 250, allowing more area in IC 232 for other structures.

Second, active layers 258, 260, and 262 are not damaged during the removal of bulk layer 254 (as in action 116 of FIG. 1B, shown in FIG. 9), since active layers 258, 260, and 262 were not exposed by the hardmask removal (as in action 114 of FIG. 1A, shown in FIG. 8). Rather active layers 258, 260, and 262 encapsulated by hardmask 266 and photoresist 268 on their sides and etch stop layer 256 on the top. Conventional techniques can fail to properly protect active layers during removal of bulk layers, due to poor encapsulation of the active layers and/or due to the protective layers not withstanding the harsh additional actions needed to completely remove the bulk layers.

Damage to active layers negatively impacts the performance of a device formed from such active layers. The present invention exhibits improved device performance due to improved protection of active layers 258, 260, and 262.

Third, since lower photoresist segment 268c has a width W2 (shown in FIG. 6) along the sidewall of bulk layer 254 that is greater than width W1 of upper photoresist segment 268b along the sidewall of bulk layer 254, it is easier to ensure that photoresist 268 remains higher than, or at least at the height of, etch stop layer 256 when removing photoresist segments (as in action 112 of FIG. 1A, shown in FIG. 7). Hardmask segment 266d situated against the sidewall of active layers 258, 260, and 262 is not exposed. When removing exposed hardmask segments (as in action 114 of FIG. 1A, shown in FIG. 8), active layers 258, 260, and 262 are not exposed, and accordingly active layers 258, 260, and 262 are not damaged when removing bulk layer 254 (as in action 116 of FIG. 1B, shown in FIG. 9).

Fourth, hardmask segment 266c (shown in FIG. 9) can have a tall protruding topography relative to active layer 256 that makes subsequent processing difficult (note that hardmask segment 266c shown in FIG. 9 is not necessarily drawn to scale, and may be significantly taller). Hardmask segment 266c can be removed (as in action 118 of FIG. 1B, shown in FIG. 10) to reduce the topography and facilitate subsequent processing, without exposing active layers 258, 260, and 262.

Fifth, because top surface 274 of blanket dielectrics 270, 272a, and 272b is substantially planar over both active layer 256 and hardmask 266 (as in action 124 of FIG. 1B, shown in FIG. 13) immediately prior forming device 278 (as in action 126 of FIG. 1B, shown in FIG. 14), forming device 278 is significantly easier. Planar topologies can be processed with more commonly available fabrication technologies, and generally facilitate better alignment during lithography, allowing for smaller devices less prone to fabrication errors.

Thus, various implementations of the present application achieve improved fabrication of semiconductor structures using bonded chiplets and novel combinations to overcome the deficiencies in the art. From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A method comprising:
providing a substrate;
bonding a chiplet to said substrate, said chiplet comprising a bulk layer and an active layer;
forming a hardmask over said chiplet;
forming a photoresist over said hardmask;
removing a photoresist segment of said photoresist to expose a first hardmask segment of said hardmask;
removing said first hardmask segment to expose said bulk layer without exposing said active layer;
removing said bulk layer;
removing a remainder of said photoresist.

2. The method of claim 1, wherein said active layer comprises gallium arsenide (GaAs) or aluminum gallium arsenide (AlGaAs).

3. The method of claim 1, wherein said substrate comprises a semiconductor-on-insulator (SOI) substrate.

4. The method of claim 1, further comprising:
forming at least one blanket dielectric over said active layer and said hardmask;
planarizing said at least one blanket dielectric.

5. The method of claim 1, further comprising forming a first device from said active layer.

6. The method of claim 5, wherein said first device is a laser, a photodiode, or an electro-absorption modulator (EAM).

7. The method of claim 5, wherein said first device is optically connected to a second device in said substrate.

8. The method of claim 1, wherein said first hardmask segment is situated over said bulk layer, and said removing said first hardmask segment exposes a top surface of said bulk layer.

9. The method of claim 1, wherein said first hardmask segment is situated against a sidewall of said bulk layer, and said removing said first hardmask segment exposes said sidewall of said bulk layer.

10. The method of claim 1, wherein said forming said photoresist comprises forming upper and lower photoresist segments along a sidewall of said bulk layer, said upper photoresist segment having a first width along said sidewall, said lower photoresist segment having a second width along said sidewall, said second width greater than said first width.

11. The method of claim 1, wherein said chiplet further comprises an etch stop layer to protect said active layer during said removing said bulk layer.

12. The method of claim 1, further comprising removing a second hardmask segment of said hardmask situated higher than said active layer after said removing said bulk layer.

13. A structure comprising:
a substrate;
a first interlayer dielectric over said substrate;
a bonding window in said first interlayer dielectric;
an optoelectronic device in said bonding window and bonded to said substrate;
a gap in said bonding window between said optoelectronic device and a sidewall of said first interlayer dielectric;
at least one first blanket dielectric in said gap and over said first interlayer dielectric, said least one first blanket dielectric having a first substantially planar top surface situated higher than a top active layer of said optoelectronic device;
a second interlayer dielectric in said gap and over said at least one first blanket dielectric and said top active layer;
a hardmask in said gap between said at least one first blanket dielectric and said second interlayer dielectric.

14. The structure of claim 13, wherein said optoelectronic device comprises gallium arsenide (GaAs) or aluminum gallium arsenide (AlGaAs).

15. The structure of claim 13, wherein said substrate comprises a semiconductor-on-insulator (SOI) substrate.

16. The structure of claim 13, wherein a top of said hardmask is at approximately the same height as a top surface of said top active layer.

17. The structure of claim 13, wherein said optoelectronic device is a laser, a photodiode, or an electro-absorption modulator (EAM).

18. The structure of claim 13, wherein said optoelectronic device is optically connected to a second device in said substrate.

19. The structure of claim 13, wherein said top active layer is configured as an etch stop for a lower active layer of said optoelectronic device.

20. The structure of claim 13, further comprising a contact metal in said second interlayer dielectric and connected to said optoelectronic device.
